(19) United States
(12) Patent Application Publication
(10) Pub. No.: US 2023/0415641 A1
(43) Pub. Date: Dec. 28, 2023

(54) VEHICLE WITH MARKER LIGHTS FOR CHARGING STATUS

(71) Applicant: Oshkosh Corporation, Oskosh, WI (US)

(72) Inventors: Amanda Miller, Oshkosh, WI (US); Jeffrey Koga, Oshkosh, WI (US); Jerry SHIRLEY, Oshkosh, WI (US); Troy Herman, Oshkosh, WI (US); Jeff Verhagen, Oshkosh, WI (US); Jon Branson, Oshkosh, WI (US)

(73) Assignee: Oshkosh Corporation, Oskosh, WI (US)

(21) Appl. No.: 18/171,101

(22) Filed: Feb. 17, 2023

Related U.S. Application Data
(60) Provisional application No. 63/356,087, filed on Jun. 28, 2022.

(51) Int. Cl. B60Q 1/50; G01R 31/371; B60L 58/10

(52) U.S. Cl. CPC B60Q 1/50; G01R 31/371; B60L 58/10

(57) ABSTRACT

A refuse vehicle includes a battery configured to power the refuse vehicle, a light, and a controller electrically coupled to the battery and the light. The controller includes one or more processors and a memory storing instructions that, when executed by the one or more processors, cause the controller to control the light to provide a safety function and/or provide visibility to a user of the refuse vehicle when the refuse vehicle is in active operation and to control the light to indicate a charge status of the battery when the refuse vehicle is not in active operation.

### CROSS-REFERENCE TO RELATED PATENT APPLICATIONS

This application claims the benefit of and priority to U.S. Provisional Application No. 63/356,087, filed Jun. 28, 2022, the entire disclosure of which is incorporated by reference herein.

### BACKGROUND

The present disclosure relates generally to vehicles. More specifically, the present disclosure relates to an electric or electric hybrid vehicle with lights that indicate the charging status of the vehicle's battery.

### SUMMARY

One embodiment relates to a refuse vehicle including a battery configured to power the refuse vehicle, a light, and a controller electrically coupled to the battery and the light. The controller includes one or more processors and a memory storing instructions that, when executed by the one or more processors, cause the controller to control the light to provide a safety function and/or provide visibility to a user of the refuse vehicle when the refuse vehicle is in active operation and to control the light to indicate a charge status of the battery when the refuse vehicle is not in active operation.

Another embodiment relates to a vehicle including a battery configured to power the vehicle, one or more lights, and a controller electrically coupled to the battery and the lights. The controller includes one or more processors and a memory storing instructions that, when executed by the one or more processors, cause the controller to control the lights to indicate a charge status of the battery when the refuse vehicle is not in active operation.

Another embodiment relates to a method of operating a battery-powered vehicle having a battery and a plurality of lights configured to provide safety functions and/or provide visibility to a user of the vehicle. The method includes determining a charge status of the battery and controlling the lights to indicate the charge status of the battery.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE DRAWINGS

FIG. 1 is a left side view of a vehicle, according to an exemplary embodiment.

FIG. 2 is a perspective view of a chassis of the vehicle of FIG. 1.

FIG. 3 is a perspective view of the vehicle of FIG. 1 configured as a front-loading refuse vehicle, according to an exemplary embodiment.

FIG. 4 is a left side view of the front-loading refuse vehicle of FIG. 3 configured with a tag axle.

FIG. 5 is a perspective view of the vehicle of FIG. 1 configured as a side-loading refuse vehicle, according to an exemplary embodiment.

FIG. 6 is a right side view of the side-loading refuse vehicle of FIG. 5.

FIG. 7 is a top view of the side-loading refuse vehicle of FIG. 5.

FIG. 8 is a left side view of the side-loading refuse vehicle of FIG. 5 configured with a tag axle.

FIG. 9 is a perspective view of the vehicle of FIG. 1 configured as a mixer vehicle, according to an exemplary embodiment.

FIG. 10 is a perspective view of the vehicle of FIG. 1 configured as a fire fighting vehicle, according to an exemplary embodiment.

FIG. 11 is a left side view of the vehicle of FIG. 1 configured as an airport fire fighting vehicle, according to an exemplary embodiment.

FIG. 12 is a perspective view of the vehicle of FIG. 1 configured as a boom lift, according to an exemplary embodiment.

FIG. 13 is a perspective view of the vehicle of FIG. 1 configured as a scissor lift, according to an exemplary embodiment.

FIG. 14 is a perspective view of a portion of a rear-loading refuse vehicle, according to an exemplary embodiment.

FIG. 15 is a diagram of a control system of the rear-loading refuse vehicle of FIG. 14, according to an exemplary embodiment.

FIG. 16 is four perspective views of a portion of the rear-loading refuse vehicle of FIG. 14.

FIG. 17 is a perspective view of a portion of the rear-loading refuse vehicle of FIG. 14.

### DETAILED DESCRIPTION

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

According to an exemplary embodiment, a vehicle includes an external light that functions both as a safety light for use when the vehicle is in active operation and as an indicator of the charging status of the vehicle. For example, the light may function as a brake light when the vehicle is in active operation and may also indicate the level of charge when the vehicle is plugged into a power source to charge the battery. This can allow a user to determine from a distance that the vehicle is being charged, as well as the state of charge of the battery.

### Overall Vehicle

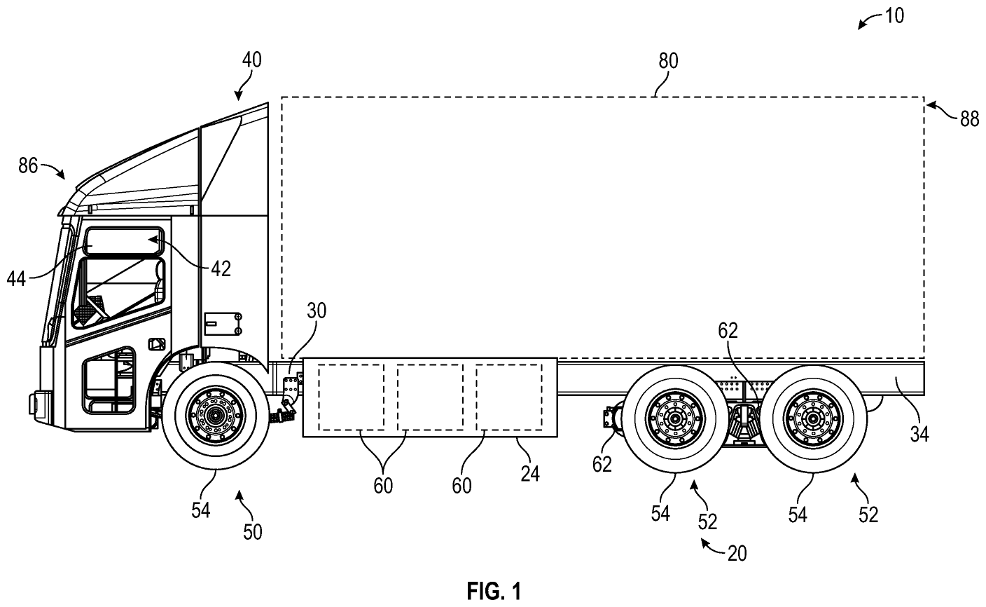

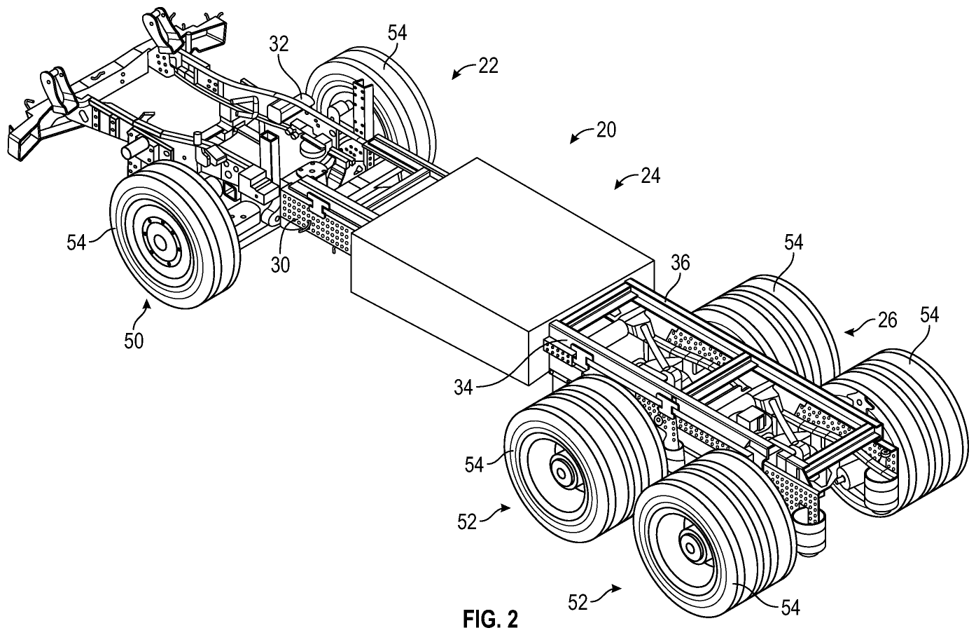

Referring to FIGS. 1 and 2, a reconfigurable vehicle (e.g., a vehicle assembly, a truck, a vehicle base, etc.) is shown as vehicle 10, according to an exemplary embodiment. As shown, the vehicle 10 includes a frame assembly or chassis assembly, shown as chassis 20, that supports other components of the vehicle 10. The chassis 20 extends longitudinally along a length of the vehicle 10, substantially parallel to a primary direction of travel of the vehicle 10. As shown, the chassis 20 includes three sections or portions, shown as front section 22, middle section 24, and rear section 26. The middle section 24 of the chassis 20 extends between the front section 22 and the rear section 26. In some embodiments, the middle section 24 of the chassis 20 couples the front section 22 to the rear section 26. In other embodiments, the front section 22 is coupled to the rear section 26 by another component (e.g., the body of the vehicle 10).

As shown in FIG. 2, the front section 22 includes a pair of frame portions, frame members, or frame rails, shown as front rail portion 30 and front rail portion 32. The rear section 26 includes a pair of frame portions, frame members, or frame rails, shown as rear rail portion 34 and rear rail portion 36. The front rail portion 30 is laterally offset from the front rail portion 32. Similarly, the rear rail portion 34 is laterally offset from the rear rail portion 36. This spacing may provide frame stiffness and space for vehicle components (e.g., batteries, motors, axles, gears, etc.) between the frame rails. In some embodiments, the front rail portions 30 and 32 and the rear rail portions 34 and 36 extend longitudinally and substantially parallel to one another. The chassis 20 may include additional structural elements (e.g., cross members that extend between and couple the frame rails).

In some embodiments, the front section 22 and the rear section 26 are configured as separate, discrete subframes (e.g., a front subframe and a rear subframe). In such embodiments, the front rail portion 30, the front rail portion 32, the rear rail portion 34, and the rear rail portion 36 are separate, discrete frame rails that are spaced apart from one another. In some embodiments, the front section 22 and the rear section 26 are each directly coupled to the middle section 24 such that the middle section 24 couples the front section 22 to the rear section 26. Accordingly, the middle section 24 may include a structural housing or frame. In other embodiments, the front section 22, the middle section 24, and the rear section 26 are coupled to one another by another component, such as a body of the vehicle 10.

In other embodiments, the front section 22, the middle section 24, and the rear section 26 are defined by a pair of frame rails that extend continuously along the entire length of the vehicle 10. In such an embodiment, the front rail portion 30 and the rear rail portion 34 would be front and rear portions of a first frame rail, and the front rail portion 32 and the rear rail portion 36 would be front and rear portions of a second frame rail. In such embodiments, the middle section 24 would include a center portion of each frame rail.

In some embodiments, the middle section 24 acts as a storage portion that includes one or more vehicle components. The middle section 24 may include an enclosure that contains one or more vehicle components and/or a frame that supports one or more vehicle components. By way of example, the middle section 24 may contain or include one or more electrical energy storage devices (e.g., batteries, capacitors, etc.). By way of another example, the middle section 24 may include fuel tanks fuel tanks. By way of yet another example, the middle section 24 may define a void space or storage volume that can be filled by a user.

A cabin, operator compartment, or body component, shown as cab 40, is coupled to a front end portion of the chassis 20 (e.g., the front section 22 of the chassis 20). Together, the chassis 20 and the cab 40 define a front end of the vehicle 10. The cab 40 extends above the chassis 20. The cab 40 includes an enclosure or main body that defines an interior volume, shown as cab interior 42, that is sized to contain one or more operators. The cab 40 also includes one or more doors 44 that facilitate selective access to the cab interior 42 from outside of the vehicle 10. The cab interior 42 contains one or more components that facilitate operation of the vehicle 10 by the operator. By way of example, the cab interior 42 may contain components that facilitate operator comfort (e.g., seats, seatbelts, etc.), user interface components that receive inputs from the operators (e.g., steering wheels, pedals, touch screens, switches, buttons, levers, etc.), and/or user interface components that provide information to the operators (e.g., lights, gauges, speakers, etc.). The user interface components within the cab 40 may facilitate operator control over the drive components of the vehicle 10 and/or over any implements of the vehicle 10.

The vehicle 10 further includes a series of axle assemblies, shown as front axle 50 and rear axles 52. As shown, the vehicle 10 includes one front axle 50 coupled to the front section 22 of the chassis 20 and two rear axles 52 each coupled to the rear section 26 of the chassis 20. In other embodiments, the vehicle 10 includes more or fewer axles. By way of example, the vehicle 10 may include a tag axle that may be raised or lowered to accommodate variations in weight being carried by the vehicle 10. The front axle 50 and the rear axles 52 each include a series of tractive elements (e.g., wheels, treads, etc.), shown as wheel and tire assemblies 54. The wheel and tire assemblies 54 are configured to engage a support surface (e.g., roads, the ground, etc.) to support and propel the vehicle 10. The front axle 50 and the rear axles may include steering components (e.g., steering arms, steering actuators, etc.), suspension components (e.g., gas springs, dampeners, air springs, etc.), power transmission or drive components (e.g., differentials, drive shafts, etc.), braking components (e.g., brake actuators, brake pads, brake discs, brake drums, etc.), and/or other components that facilitate propulsion or support of the vehicle.

In some embodiments, the vehicle 10 is configured as an electric vehicle that is propelled by an electric powertrain system. Referring to FIG. 1, the vehicle 10 includes one or more electrical energy storage devices (e.g., batteries, capacitors, etc.), shown as batteries 60. As shown, the batteries 60 are positioned within the middle section 24 of the chassis 20. In other embodiments, the batteries 60 are otherwise positioned throughout the vehicle 10. The vehicle 10 further includes one or more electromagnetic devices or prime movers (e.g., motor/generators), shown as drive motors 62. The drive motors 62 are electrically coupled to the batteries 60. The drive motors 62 may be configured to receive electrical energy from the batteries 60 and provide rotational mechanical energy to the wheel and tire assemblies 54 to propel the vehicle 10. The drive motors 62 may be configured to receive rotational mechanical energy from the wheel and tire assemblies 64 and provide electrical energy to the batteries 60, providing a braking force to slow the vehicle 10.

The batteries 60 may include one or more rechargeable batteries (e.g., lithium-ion batteries, nickel-metal hydride batteries, lithium-ion polymer batteries, lead-acid batteries, nickel-cadmium batteries, etc.). The batteries 60 may be charged by one or more sources of electrical energy onboard the vehicle 10 (e.g., solar panels, etc.) or separate from the vehicle 10 (e.g., connections to an electrical power grid, a wireless charging system, etc.). As shown, the drive motors 62 are positioned within the rear axles 52 (e.g., as part of a combined axle and motor assembly). In other embodiments, the drive motors 62 are otherwise positioned within the vehicle 10.

In other embodiments, the vehicle 10 is configured as a hybrid vehicle that is propelled by a hybrid powertrain system (e.g., a diesel/electric hybrid, gasoline/electric hybrid, natural gas/electric hybrid, etc.). According to an exemplary embodiment, the hybrid powertrain system may include a primary driver (e.g., an engine, a motor, etc.), an energy generation device (e.g., a generator, etc.), and/or an energy storage device (e.g., a battery, capacitors, ultra-capacitors, etc.) electrically coupled to the energy generation device. The primary driver may combust fuel (e.g., gasoline, diesel, etc.) to provide mechanical energy, which a transmission may receive and provide to the axle front axle 50 and/or the rear axles 52 to propel the vehicle 10. Additionally or alternatively, the primary driver may provide mechanical energy to the generator, which converts the mechanical energy into electrical energy. The electrical energy may be stored in the energy storage device (e.g., the batteries 60) in order to later be provided to a motive driver.

In yet other embodiments, the chassis 20 may further be configured to support non-hybrid powertrains. For example, the powertrain system may include a primary driver that is a compression-ignition internal combustion engine that utilizes diesel fuel.

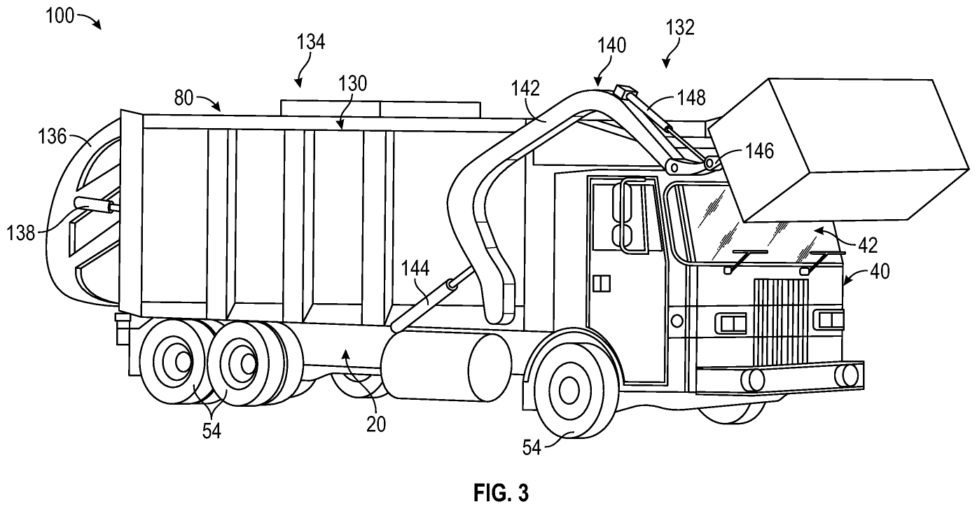

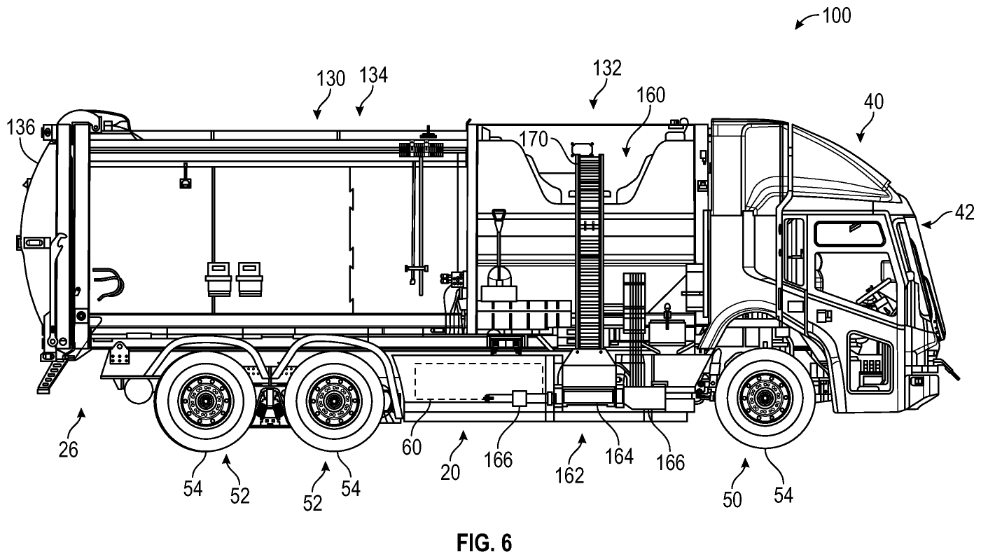

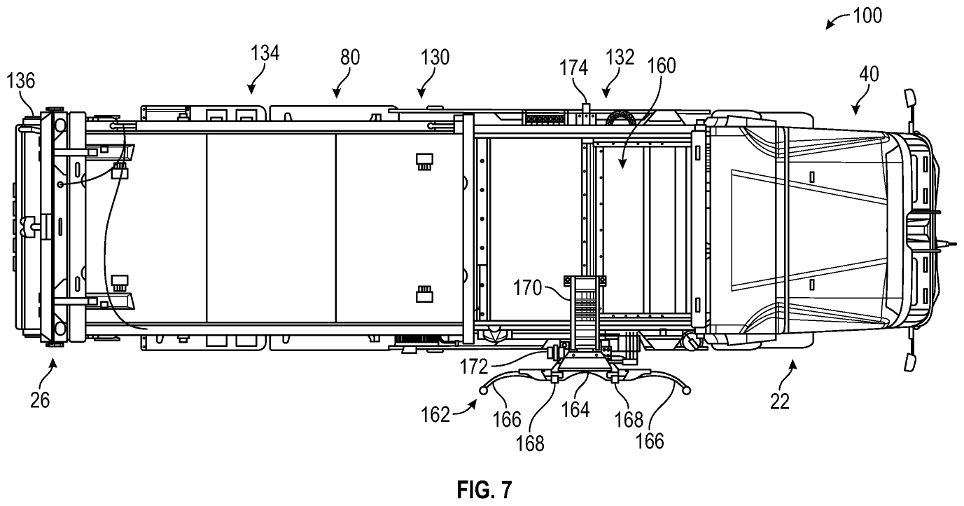

Referring to FIG. 1, the vehicle 10 includes a rear assembly, module, implement, body, or cargo area, shown as application kit 80. The application kit 80 may include one or more implements, vehicle bodies, and/or other components. Although the application kit 80 is shown positioned behind the cab 40, in other embodiments the application kit 80 extends forward of the cab 40. The vehicle 10 may be outfitted with a variety of different application kits 80 to configure the vehicle 10 for use in different applications. Accordingly, a common vehicle 10 can be configured for a variety of different uses simply by selecting an appropriate application kit 80. By way of example, the vehicle 10 may be configured as a refuse vehicle, a concrete mixer, a fire fighting vehicle, an airport fire fighting vehicle, a lift device (e.g., a boom lift, a scissor lift, a telehandler, a vertical lift, etc.), a crane, a tow truck, a military vehicle, a delivery vehicle, a mail vehicle, a boom truck, a plow truck, a farming machine or vehicle, a construction machine or vehicle, a coach bus, a school bus, a semi-truck, a passenger or work vehicle (e.g., a sedan, a SUV, a truck, a van, etc.), and/or still another vehicle. FIGS. 3-13 illustrate various examples of how the vehicle 10 may be configured for specific applications. Although only a certain set of vehicle configurations is shown, it should be understood that the vehicle 10 may be configured for use in other applications that are not shown.

The application kit 80 may include various actuators to facilitate certain functions of the vehicle 10. By way of example, the application kit 80 may include hydraulic actuators (e.g., hydraulic cylinders, hydraulic motors, etc.), pneumatic actuators (e.g., pneumatic cylinders, pneumatic motors, etc.), and/or electrical actuators (e.g., electric motors, electric linear actuators, etc.). The application kit 80 may include components that facilitate operation of and/or control of these actuators. By way of example, the application kit 80 may include hydraulic or pneumatic components that form a hydraulic or pneumatic circuit (e.g., conduits, valves, pumps, compressors, gauges, reservoirs, accumulators, etc.). By way of another example, the application kit 80 may include electrical components (e.g., batteries, capacitors, voltage regulators, motor controllers, etc.). The actuators may be powered by components of the vehicle By way of example, the actuators may be powered by the batteries 60, the drive motors 62, or the primary driver (e.g., through a power take off).

The vehicle 10 generally extends longitudinally from a front side 86 to a rear side 88. The front side 86 is defined by the cab 40 and/or the chassis. The rear side 88 is defined by the application kit 80 and/or the chassis 20. The primary, forward direction of travel of the vehicle is longitudinal, with the front side 86 being arranged forward of the rear side 88.

### A. Front-Loading Refuse Vehicle

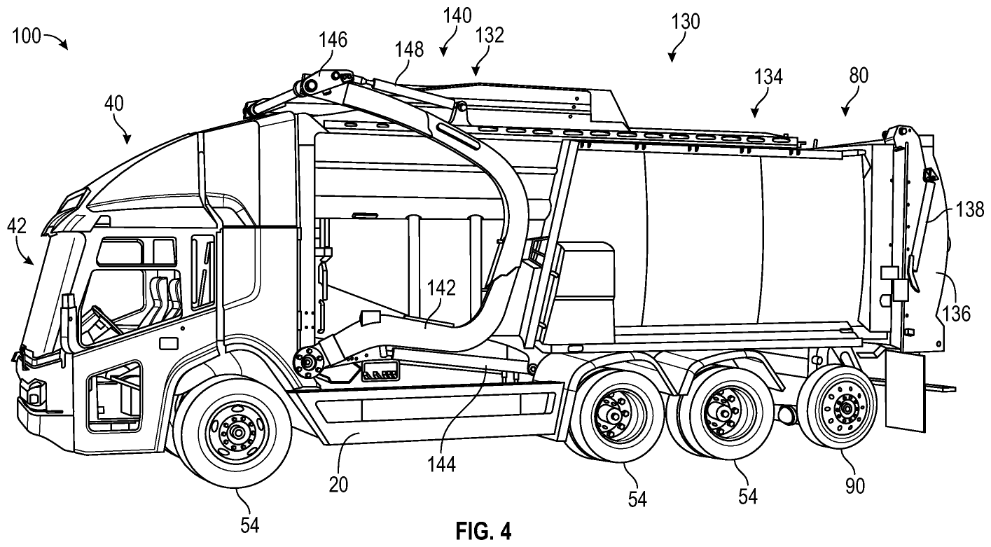

Referring now to FIGS. 3 and 4, the vehicle 10 is configured as a refuse vehicle 100 (e.g., a refuse truck, a garbage truck, a waste collection truck, a sanitation truck, a recycling truck, etc.). Specifically, the refuse vehicle 100 is a front-loading refuse vehicle. In other embodiments, the refuse vehicle 100 is configured as a rear-loading refuse vehicle or a front-loading refuse vehicle. The refuse vehicle 100 may be configured to transport refuse from various waste receptacles (e.g., refuse containers) within a municipality to a storage and/or processing facility (e.g., a landfill, an incineration facility, a recycling facility, etc.).

FIG. 4 illustrates the refuse vehicle 100 of FIG. 3 configured with a liftable axle, shown as tag axle 90, including a pair of wheel and tire assemblies 54. As shown, the tag axle 90 is positioned reward of the rear axles 52. The tag axle 90 can be selectively raised and lowered (e.g., by a hydraulic actuator) to selectively engage the wheel and tire assemblies 54 of the tag axle 90 with the ground. The tag axle 90 may be raised to reduce rolling resistance experienced by the refuse vehicle 100. The tag axle 90 may be lowered to distribute the loaded weight of the vehicle 100 across a greater number of a wheel and tire assemblies 54 (e.g., when the refuse vehicle 100 is loaded with refuse).

As shown in FIGS. 3 and 4, the application kit 80 of the refuse vehicle 100 includes a series of panels that form a rear body or container, shown as refuse compartment 130. The refuse compartment 130 may facilitate transporting refuse from various waste receptacles within a municipality to a storage and/or a processing facility (e.g., a landfill, an incineration facility, a recycling facility, etc.). By way of example, loose refuse may be placed into the refuse compartment 130 where it may be compacted (e.g., by a packer system within the refuse compartment 130). The refuse compartment 130 may also provide temporary storage for refuse during transport to a waste disposal site and/or a recycling facility. In some embodiments, the refuse compartment 130 may define a hopper volume 132 and storage volume 134. In this regard, refuse may be initially loaded into the hopper volume 132 and later compacted into the storage volume 134. As shown, the hopper volume 132 is positioned between the storage volume 134 and the cab 40 (e.g., refuse is loaded into a portion of the refuse compartment 130 behind the cab 40 and stored in a portion further toward the rear of the refuse compartment 130). In other embodiments, the storage volume may be positioned between the hopper volume and the cab 40 (e.g., in a rear-loading refuse truck, etc.). The application kit 80 of the refuse vehicle 100 further includes a pivotable rear portion, shown as tailgate 136, that is pivotally coupled to the refuse compartment 130. The tailgate 136 may be selectively repositionable between a closed position and an open position by an actuator (e.g., a hydraulic cylinder, an electric linear actuator, etc.), shown as tailgate actuator 138 (e.g., to facilitate emptying the storage volume).

As shown in FIGS. 3 and 4, the refuse vehicle 100 also includes an implement, shown as lift assembly 140, which is a front-loading lift assembly. According to an exemplary embodiment, the lift assembly 140 includes a pair of lift arms 142 and a pair of actuators (e.g., hydraulic cylinders, electric linear actuators, etc.), shown as lift arm actuators 144. The lift arms 142 may be rotatably coupled to the chassis 20 and/or the refuse compartment 130 on each side of the refuse vehicle 100 (e.g., through a pivot, a lug, a shaft, etc.), such that the lift assembly 140 may extend forward relative to the cab 40 (e.g., a front-loading refuse truck, etc.). In other embodiments, the lift assembly 140 may extend rearward relative to the application kit 80 (e.g., a rear-loading refuse truck). As shown in FIGS. 3 and 4, in an exemplary embodiment the lift arm actuators 144 may be positioned such that extension and retraction of the lift arm actuators 144 rotates the lift arms 142 about an axis extending through the pivot. In this regard, the lift arms 142 may be rotated by the lift arm actuators 144 to lift a refuse container over the cab 40. The lift assembly 140 further includes a pair of interface members, shown as lift forks 146, each pivotally coupled to a distal end of one of the lift arms 142. The lift forks 146 may be configured to engage a refuse container (e.g., a dumpster) to selectively coupled the refuse container to the lift arms 142. By way of example, each of the lift forks 146 may be received within a corresponding pocket defined by the refuse container. A pair of actuators (e.g., hydraulic cylinders, electric linear actuators, etc.), shown as articulation actuators 148, are each coupled to one of the lift arms 142 and one of the lift forks 146. The articulation actuators 148 may be positioned to rotate the lift forks 146 relative to the lift arms 142 about a horizontal axis. Accordingly, the articulation actuators 148 may assist in tipping refuse out of the refuse container and into the refuse compartment 130. The lift arm actuators 144 may then rotate the lift arms 142 to return the empty refuse container to the ground.

### B. Side-Loading Refuse Vehicle

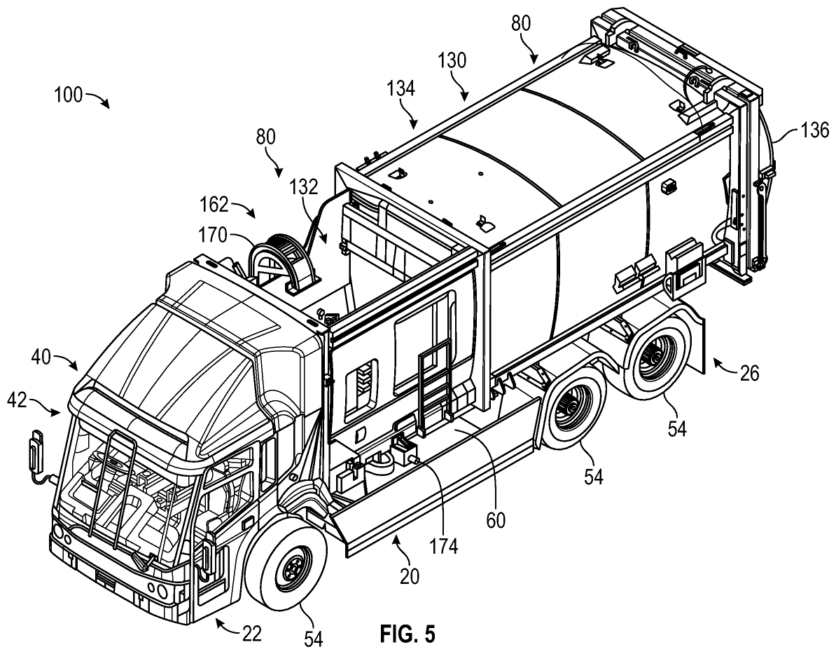

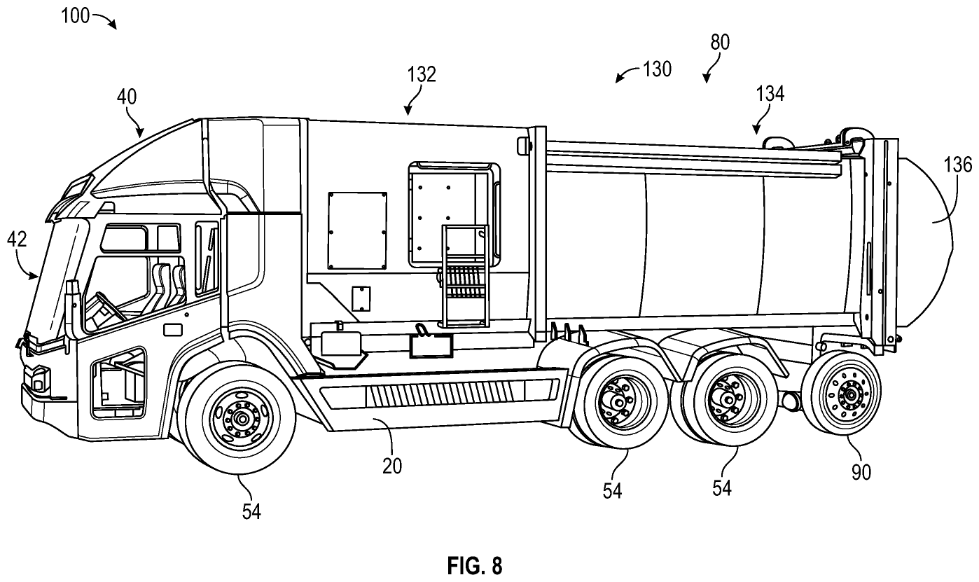

Referring now to FIGS. 5-8, an alternative configuration of the refuse vehicle 100 is shown according to an exemplary embodiment. Specifically, the refuse vehicle 100 of FIGS. 5-8 is configured as a side-loading refuse vehicle. The refuse vehicle 100 of FIGS. 5-8 may be substantially similar to the front-loading refuse vehicle 100 of FIGS. 3 and 4 except as otherwise specified herein. As shown, the refuse vehicle 100 of FIGS. 5-7 is configured with a tag axle 90 in FIG. 8.

Referring still to FIGS. 5-8, the refuse vehicle 100 omits the lift assembly 140 and instead includes a side-loading lift assembly, shown as lift assembly 160, that extends laterally outward from a side of the refuse vehicle 100. The lift assembly 160 includes an interface assembly, shown as grabber assembly 162, that is configured to engage a refuse container (e.g., a residential garbage can) to selectively couple the refuse container to the lift assembly 160. The grabber assembly 162 includes a main portion, shown as main body 164, and a pair of fingers or interface members, shown as grabber fingers 166. The grabber fingers 166 are pivotally coupled to the main body 164 such that the grabber fingers 166 are each rotatable about a vertical axis. A pair of actuators (e.g., hydraulic motors, electric motors, etc.), shown as finger actuators 168, are configured to control movement of the grabber fingers 166 relative to the main body 164.

The grabber assembly 162 is movably coupled to a guide, shown as track 170, that extends vertically along a side of the refuse vehicle 100. Specifically, the main body 164 is slidably coupled to the track 170 such that the main body 164 is repositionable along a length of the track 170. An actuator (e.g., a hydraulic motor, an electric motor, etc.), shown as lift actuator 172, is configured to control movement of the grabber assembly 162 along the length of the track 170. In some embodiments, a bottom end portion of the track 170 is straight and substantially vertical such that the grabber assembly 162 raises or lowers a refuse container when moving along the bottom end portion of the track 170. In some embodiments, a top end portion of the track 170 is curved such that the grabber assembly 162 inverts a refuse container to dump refuse into the hopper volume 132 when moving along the top end portion of the track 170.

The lift assembly 160 further includes an actuator (e.g., a hydraulic cylinder, an electric linear actuator, etc.), shown as track actuator 174, that is configured to control lateral movement of the grabber assembly 162. By way of example, the track actuator 174 may be coupled to the chassis 20 and the track 170 such that the track actuator 174 moves the track 170 and the grabber assembly 162 laterally relative to the chassis 20. The track actuator 174 may facilitate repositioning the grabber assembly 162 to pick up and replace refuse containers that are spaced laterally outward from the refuse vehicle 100.

### C. Concrete Mixer Truck

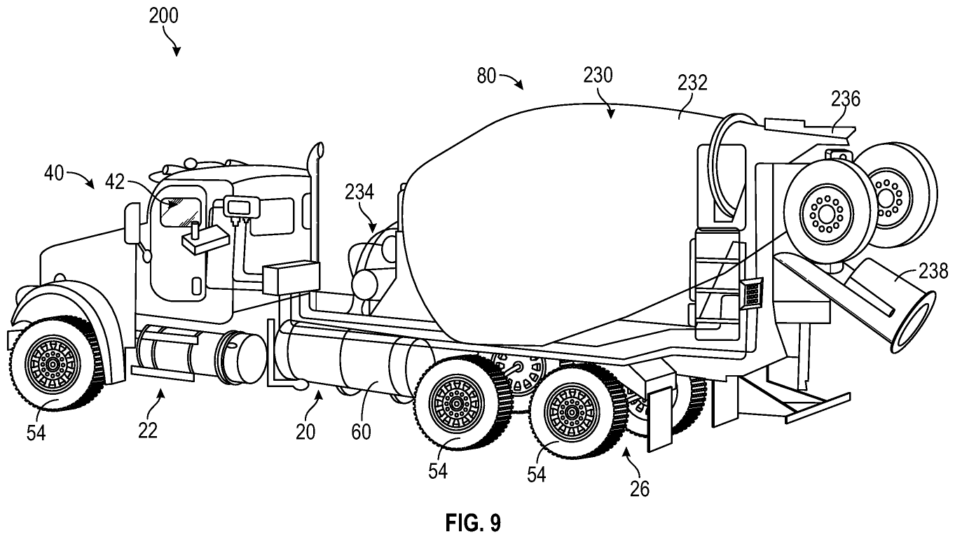

Referring now to FIG. 9, the vehicle 10 is configured as a mixer truck (e.g., a concrete mixer truck, a mixer vehicle, etc.), shown as mixer truck 200. Specifically, the mixer truck 200 is shown as a rear-discharge concrete mixer truck. In other embodiments, the mixer truck 200 is a front-discharge concrete mixer truck.

As shown in FIG. 9, the application kit 80 includes a mixing drum assembly (e.g., a concrete mixing drum), shown as drum assembly 230. The drum assembly 230 may include a mixing drum 232, a drum drive system 234 (e.g., a rotational actuator or motor, such as an electric motor or hydraulic motor), an inlet portion, shown as hopper 236, and an outlet portion, shown as chute 238. The mixing drum 232 may be coupled to the chassis 20 and may be disposed behind the cab 40 (e.g., at the rear and/or middle of the chassis 20). In an exemplary embodiment, the drum drive system 234 is coupled to the chassis 20 and configured to selectively rotate the mixing drum 232 about a central, longitudinal axis. According to an exemplary embodiment, the central, longitudinal axis of the mixing drum 232 may be elevated from the chassis 20 (e.g., from a horizontal plane extending along the chassis 20) at an angle in the range of five degrees to twenty degrees. In other embodiments, the central, longitudinal axis may be elevated by less than five degrees (e.g., four degrees, etc.). In yet another embodiment, the mixer truck 200 may include an actuator positioned to facilitate adjusting the central, longitudinal axis to a desired or target angle (e.g., manually in response to an operator input/command, automatically according to a control system, etc.).

The mixing drum 232 may be configured to receive a mixture, such as a concrete mixture (e.g., cementitious material, aggregate, sand, etc.), through the hopper 236. In some embodiments, the mixer truck 200 includes an injection system (e.g., a series of nozzles, hoses, and/or valves) including an injection valve that selectively fluidly couples a supply of fluid to the inner volume of the mixing drum 232. By way of example, the injection system may be used to inject water and/or chemicals (e.g., air entrainers, water reducers, set retarders, set accelerators, superplasticizers, corrosion inhibitors, coloring, calcium chloride, minerals, and/or other concrete additives, etc.) into the mixing drum 232. The injection valve may facilitate injecting water and/or chemicals from a fluid reservoir (e.g., a water tank, etc.) into the mixing drum 232, while preventing the mixture in the mixing drum 232 from exiting the mixing drum 232 through the injection system. In some embodiments, one or more mixing elements (e.g., fins, etc.) may be positioned in the interior of the mixing drum 232, and may be configured to agitate the contents of the mixture when the mixing drum 232 is rotated in a first direction (e.g., counterclockwise, clockwise, etc.), and drive the mixture out through the chute 238 when the mixing drum 232 is rotated in a second direction (e.g., clockwise, counterclockwise, etc.). In some embodiments, the chute 238 may also include an actuator positioned such that the chute 238 may be selectively pivotable to position the chute 238 (e.g., vertically, laterally, etc.), for example at an angle at which the mixture is expelled from the mixing drum 232.

### D. Fire Truck

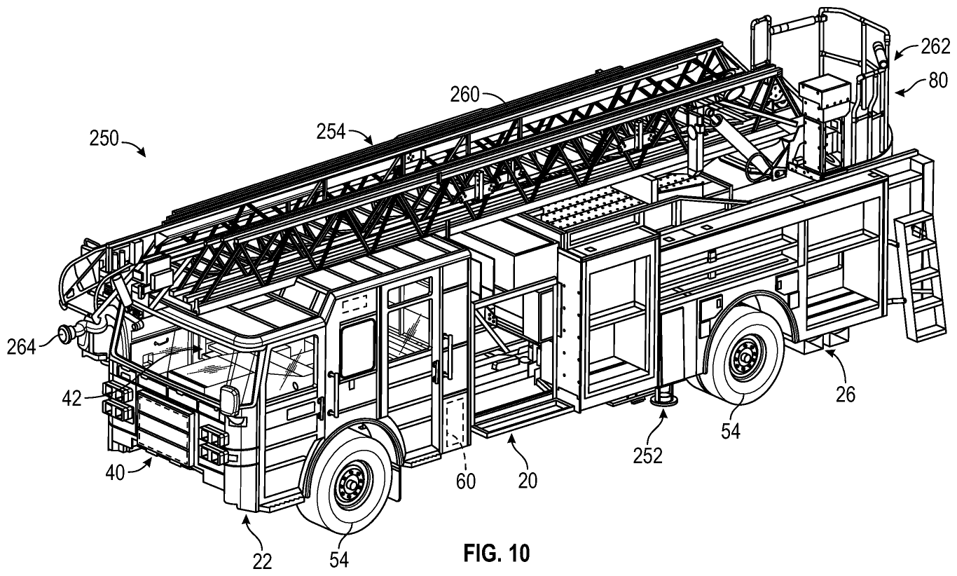

Referring now to FIG. 10, the vehicle 10 is configured as a fire fighting vehicle, fire truck, or fire apparatus (e.g., a turntable ladder truck, a pumper truck, a quint, etc.), shown as fire fighting vehicle 250. In the embodiment shown in FIG. 10, the fire fighting vehicle 250 is configured as a rear-mount aerial ladder truck. In other embodiments, the fire fighting vehicle 250 is configured as a mid-mount aerial ladder truck, a quint fire truck (e.g., including an on-board water storage, a hose storage, a water pump, etc.), a tiller fire truck, a pumper truck (e.g., without an aerial ladder), or another type of response vehicle. By way of example, the vehicle 10 may be configured as a police vehicle, an ambulance, a tow truck, or still other vehicles used for responding to a scene (e.g., an accident, a fire, an incident, etc.).

As shown in FIG. 10, in the fire fighting vehicle 250, the application kit 80 is positioned mainly rearward from the cab 40. The application kit 80 includes deployable stabilizers (e.g., outriggers, downriggers, etc.), shown as outriggers 252, that are coupled to the chassis 20. The outriggers 252 may be configured to selectively extend from each lateral side and/or the rear of the fire fighting vehicle 250 and engage a support surface (e.g., the ground) in order to provide increased stability while the fire fighting vehicle 250 is stationary. The fire fighting vehicle 250 further includes an extendable or telescoping ladder assembly, shown as ladder assembly 254. The increased stability provided by the outriggers 252 is desirable when the ladder assembly 254 is in use (e.g., extended from the fire fighting vehicle 250) to prevent tipping. In some embodiments, the application kit 80 further includes various storage compartments (e.g., cabinets, lockers, etc.) that may be selectively opened and/or accessed for storage and/or component inspection, maintenance, and/or replacement.

As shown in FIG. 10, the ladder assembly 254 includes a series of ladder sections 260 that are slidably coupled with one another such that the ladder sections 260 may extend and/or retract (e.g., telescope) relative to one another to selectively vary a length of the ladder assembly 254. A base platform, shown as turntable 262, is rotatably coupled to the chassis 20 and to a proximal end of a base ladder section 260 (i.e., the most proximal of the ladder sections 260). The turntable 262 may be configured to rotate about a vertical axis relative to the chassis 20 to rotate the ladder sections 260 about the vertical axis (e.g., up to 360 degrees, etc.). The ladder sections 260 may rotate relative to the turntable 262 about a substantially horizontal axis to selectively raise and lower the ladder sections 260 relative to the chassis 20. As shown, a water turret or implement, shown as monitor 264, is coupled to a distal end of a fly ladder section 260 (i.e., the most distal of the ladder sections 260). The monitor 264 may be configured to expel water and/or a fire suppressing agent (e.g., foam, etc.) from a water storage tank and/or an agent tank onboard the fire fighting vehicle 250, and/or from an external source (e.g., a fire hydrant, a separate water/pumper truck, etc.). In some embodiments, the ladder assembly 254 further includes an aerial platform coupled to the distal end of the fly ladder section 260 and configured to support one or more operators.

### E. ARFF Truck

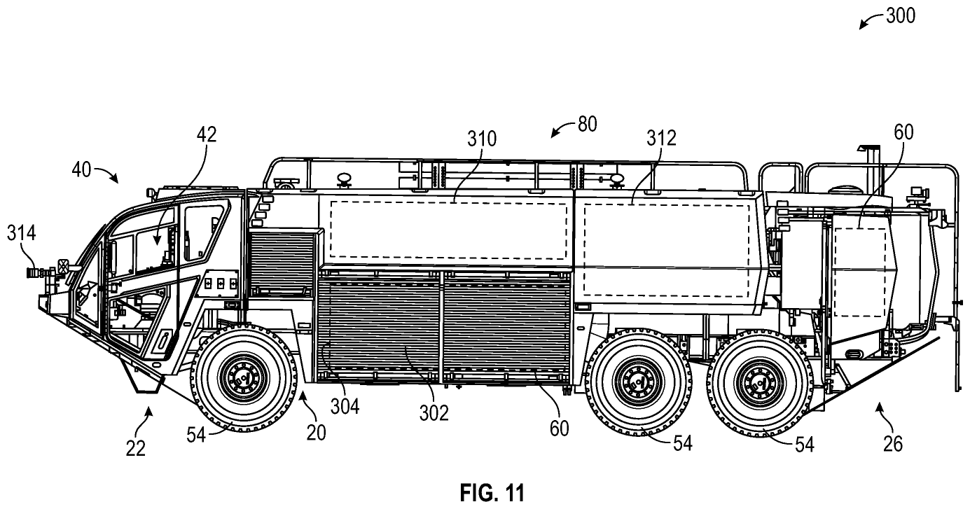

Referring now to FIG. 11, the vehicle 10 is configured as a fire fighting vehicle, shown as airport rescue and fire fighting (ARFF) truck 300. As shown in FIG. 11, the application kit 80 is positioned primarily rearward of the cab 40. As shown, the application kit 80 includes a series of storage compartments or cabinets, shown as compartments 302, that are coupled to the chassis The compartments 302 may store various equipment or components of the ARFF truck 300.

The application kit 80 includes a pump system 304 (e.g., an ultra-high-pressure pump system, etc.) positioned within one of the compartments 302 near the center of the ARFF truck 300. The application kit 80 further includes a water tank 310, an agent tank 312, and an implement or water turret, shown as monitor 314. The pump system 304 may include a high pressure pump and/or a low pressure pump, which may be fluidly coupled to the water tank 310 and/or the agent tank 312. The pump system 304 may to pump water and/or fire suppressing agent from the water tank 310 and the agent tank 312, respectively, to the monitor 314. The monitor 314 may be selectively reoriented by an operator to adjust a direction of a stream of water and/or agent. As shown in FIG. 11, the monitor 314 is coupled to a front end of the cab 40.

### F. Boom Lift

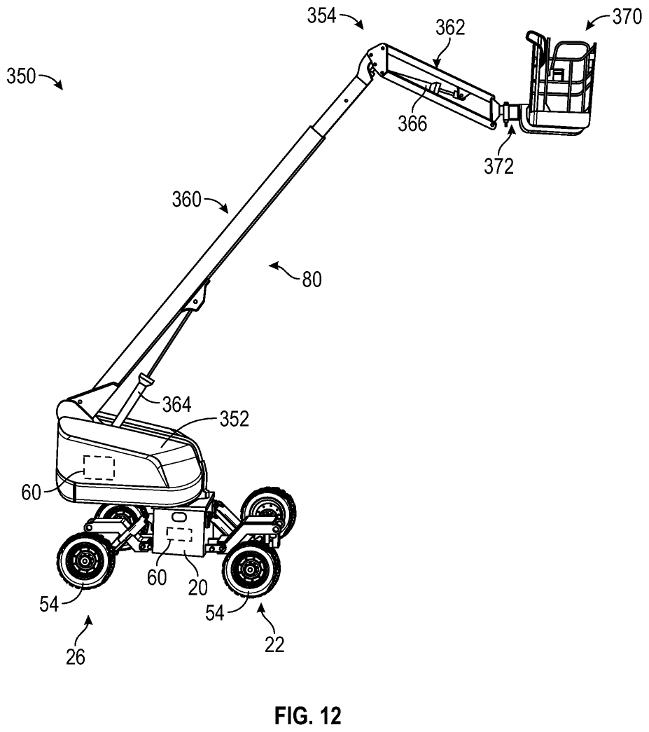

Referring now to FIG. 12, the vehicle 10 is configured as a lift device, shown as boom lift 350. The boom lift 350 may be configured to support and elevate one or more operators. In other embodiments, the vehicle 10 is configured as another type of lift device that is configured to lift operators and/or material, such as a skid-loader, a telehandler, a scissor lift, a fork lift, a vertical lift, and/or any other type of lift device or machine.

As shown in FIG. 12, the application kit 80 includes a base assembly, shown as turntable 352, that is rotatably coupled to the chassis 20. The turntable 352 may be configured to selectively rotate relative to the chassis 20 about a substantially vertical axis. In some embodiments, the turntable 352 includes a counterweight (e.g., the batteries) positioned near the rear of the turntable 352. The turntable 352 is rotatably coupled to a lift assembly, shown as boom assembly 354. The boom assembly 354 includes a first section or telescoping boom section, shown as lower boom 360. The lower boom 360 includes a series of nested boom sections that extend and retract (e.g., telescope) relative to one another to vary a length of the boom assembly 354. The boom assembly 354 further includes a second boom section or four bar linkage, shown as upper boom 362. The upper boom 362 may includes structural members that rotate relative to one another to raise and lower a distal end of the boom assembly 354. In other embodiments, the boom assembly 354 includes more or fewer boom sections (e.g., one, three, five, etc.) and/or a different arrangement of boom sections.

As shown in FIG. 12, the boom assembly 354 includes a first actuator, shown as lower lift cylinder 364. The lower boom 360 is pivotally coupled (e.g., pinned, etc.) to the turntable 352 at a joint or lower boom pivot point. The lower lift cylinder 364 (e.g., a pneumatic cylinder, an electric linear actuator, a hydraulic cylinder, etc.) is coupled to the turntable 352 at a first end and coupled to the lower boom 360 at a second end. The lower lift cylinder 364 may be configured to raise and lower the lower boom 360 relative to the turntable 352 about the lower boom pivot point.

The boom assembly 354 further includes a second actuator, shown as upper lift cylinder 366. The upper boom 362 is pivotally coupled (e.g., pinned) to the upper end of the lower boom 360 at a joint or upper boom pivot point. The upper lift cylinder 366 (e.g., a pneumatic cylinder, an electric linear actuator, a hydraulic cylinder, etc.) is coupled to the upper boom 362. The upper lift cylinder 366 may be configured to extend and retract to actuate (e.g., lift, rotate, elevate, etc.) the upper boom 362, thereby raising and lowering a distal end of the upper boom 362.

Referring still to FIG. 12, the application kit 80 further includes an operator platform, shown as platform assembly 370, coupled to the distal end of the upper boom 362 by an extension arm, shown as jib arm 372. The jib arm 372 may be configured to pivot the platform assembly 370 about a lateral axis (e.g., to move the platform assembly 370 up and down, etc.) and/or about a vertical axis (e.g., to move the platform assembly 370 left and right, etc.).

The platform assembly 370 provides a platform configured to support one or more operators or users. In some embodiments, the platform assembly 370 may include accessories or tools configured for use by the operators. For example, the platform assembly 370 may include pneumatic tools (e.g., an impact wrench, airbrush, nail gun, ratchet, etc.), plasma cutters, welders, spotlights, etc. In some embodiments, the platform assembly 370 includes a control panel (e.g., a user interface, a removable or detachable control panel, etc.) configured to control operation of the boom lift 350 (e.g., the turntable 352, the boom assembly 354, etc.) from the platform assembly 370 or remotely. In other embodiments, the platform assembly 370 is omitted, and the boom lift 350 includes an accessory and/or tool (e.g., forklift forks, etc.) coupled to the distal end of the boom assembly 354.

### G. Scissor Lift

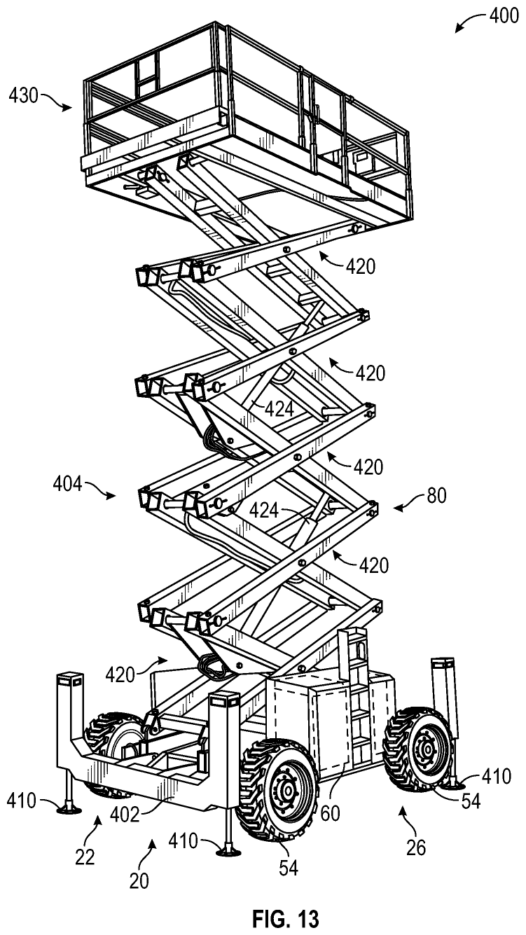

Referring now to FIG. 13, the vehicle 10 is configured as a lift device, shown as scissor lift 400. As shown in FIG. 13, the application kit 80 includes a body, shown as lift base 402, coupled to the chassis 20. The lift base 402 is coupled to a scissor assembly, shown as lift assembly 404, such that the lift base 402 supports the lift assembly 404. The lift assembly 404 is configured to extend and retract, raising and lowering between a raised position and a lowered position relative to the lift base 402.

As shown in FIG. 13, the lift base 402 includes a series of actuators, stabilizers, downriggers, or outriggers, shown as leveling actuators 410. The leveling actuators 410 may extend and retract vertically between a stored position and a deployed position. In the stored position, the leveling actuators 410 may be raised, such that the leveling actuators 410 do not contact the ground. Conversely, in the deployed position, the leveling actuators 410 may engage the ground to lift the lift base 402. The length of each of the leveling actuators 410 in their respective deployed positions may be varied in order to adjust the pitch (e.g., rotational position about a lateral axis) and the roll (e.g., rotational position about a longitudinal axis) of the lift base 402 and/or the chassis 20. Accordingly, the lengths of the leveling actuators 410 in their respective deployed positions may be adjusted to level the lift base 402 with respect to the direction of gravity (e.g., on uneven, sloped, pitted, etc. terrain). The leveling actuators 410 may lift the wheel and tire assemblies 54 off of the ground to prevent movement of the scissor lift 400 during operation. In other embodiments, the leveling actuators 410 are omitted.

The lift assembly 404 may include a series of subassemblies, shown as scissor layers 420, each including a pair of inner members and a pair of outer members pivotally coupled to one another. The scissor layers 420 may be stacked atop one another in order to form the lift assembly 404, such that movement of one scissor layer 420 causes a similar movement in all of the other scissor layers 420. The scissor layers 420 extend between and couple the lift base 402 and an operator platform (e.g., the platform assembly 430). In some embodiments, scissor layers 420 may be added to, or removed from, the lift assembly 404 in order to increase, or decrease, the fully extended height of the lift assembly 404.

Referring still to FIG. 13, the lift assembly 404 may also include one or more lift actuators 424 (e.g., hydraulic cylinders, pneumatic cylinders, electric linear actuators such as motor-driven leadscrews, etc.) configured to extend and retract the lift assembly 404. The lift actuators 424 may be pivotally coupled to inner members of various scissor layers 420, or otherwise arranged within the lift assembly 404.

A distal or upper end of the lift assembly 404 is coupled to an operator platform, shown as platform assembly 430. The platform assembly 430 may perform similar functions to the platform assembly 370, such as supporting one or more operators, accessories, and/or tools. The platform assembly 430 may include a control panel to control operation of the scissor lift 400. The lift actuators 424 may be configured to actuate the lift assembly 404 to selectively reposition the platform assembly 430 between a lowered position (e.g., where the platform assembly 430 is proximate to the lift base 402) and a raised position (e.g., where the platform assembly 430 is at an elevated height relative to the lift base 402). Specifically, in some embodiments, extension of the lift actuators 424 moves the platform assembly 430 upward (e.g., extending the lift assembly 404), and retraction of the lift actuators 424 moves the platform assembly 430 downward (e.g., retracting the lift assembly 404). In other embodiments, extension of the lift actuators 424 retracts the lift assembly 404, and retraction of the lift actuators 424 extends the lift assembly 404.

### Marker Lights for Charging Status

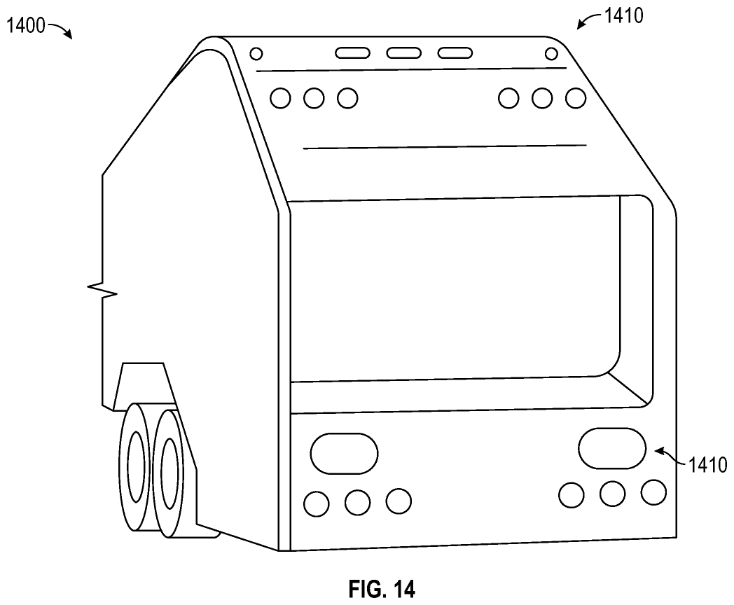

Referring now to FIG. 14, a portion of a vehicle 1400 is shown, according to some embodiments. The vehicle 1400 of FIG. 14 is shown as a rear-loading refuse truck. However, it should be understood that the embodiments described herein can be applied to any of vehicle or machine, including the vehicles and machines described in detail above. The vehicle 1400 includes one or more lights 1410. The lights 1410 may be, for example, tail lights, directional indicators, brake lights, headlights, in-cabin lights, backup lights, daytime running lights, hazard lights, or any other lights used in the operation of the vehicle 1400. During active operation of the vehicle 1400, the lights 1410 may provide safety functions, such as improving the visibility of the vehicle 1400, improving the visibility of the area around the vehicle 1400, improving the visibility inside the cabin (e.g., the cab 40), indicating that the vehicle is in a reverse gear, indicating that the brake is engaged, indicating that the operator intends to turn or change lanes, etc.

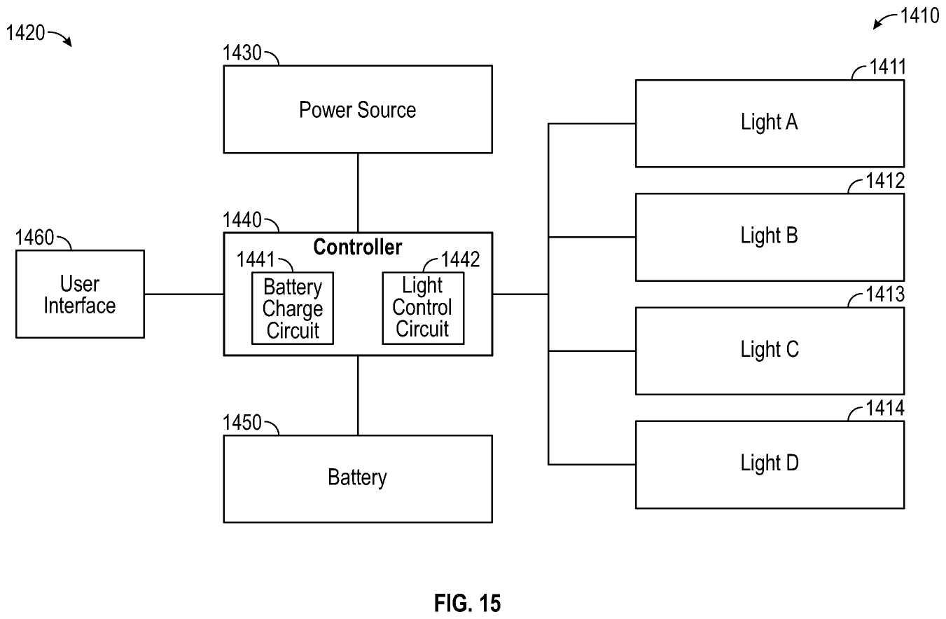

Referring now to FIG. 15, a control system 1420 for controlling the lights 1410 is shown, according to some embodiments. The system includes a power source 1430, a controller 1440 (e.g., an electronic control unit), a battery 1450 or batteries (e.g., batteries 60), and the lights 1410. The power source 1430 (e.g., an external power supply, an external power source, etc.) may be, for example, a utility power supply or a generator. The power source 1430 may be coupled to the vehicle 1400, e.g., via a charging cable, as is common with electric and plugin hybrid vehicles, though other known charging methods are also contemplated. The controller 1440 is electrically coupled to the battery 1450 and the lights 1410. The controller 1440 may include one or more processors and one or more memories. The one or more memories may store instructions that can be executed by the one or more processors to perform the functions of the controller. The battery 1450 may supply power to the lights and to other components of the vehicle 1400, such as the prime mover (e.g., drive motor 62). In some embodiments, the power source 1430, rather than the battery 1450, may supply power directly to the lights (e.g., via the controller 1440), without the power first flowing into the battery 1450, when the power source 1430 is connected to the vehicle 1400. In some embodiments, the battery 1450 supplies power to the prime mover and to other batteries. For example, the battery 1450 may be a high voltage battery that powers the drive motor 62 and also supplies power to charge low voltage batteries that are used to power other electrical components, such as the lights 1410. It will be understood that when the battery 1450 is described herein as supplying power to various components, including the lights 1410, the battery 1450 may be indirectly supplying power by charging low voltage batteries that directly power those components. In still further embodiments, some components may be powered by batteries that are charged separately from the battery 1450.

The controller 1440 includes a battery charge circuit 1441, which controls the charging of the battery 1450 by allowing power to flow from the power source 1430 to the battery 1450. The battery charge circuit 1441 monitors a charge status of the battery 1450 (e.g., the charge level, the amount of charge, the state of charge, whether the battery 1450 is currently being charged etc.). The battery charge circuit 1441 may allow electricity to flow from the power source 1430 to the battery 1450 until the battery 1450 is fully charged and may stop the flow of electricity to the battery 1450 when the battery 1450 is fully charged. The controller 1440 also includes a light control circuit 1442. The light control circuit 1442 controls the lights 1410 by selectively allowing power to flow from the battery 1450 to the lights 1410. For example, the light control circuit 1442 may turn the lights 1410 on or off, may brighten or dim the lights 1410, may illuminate only a portion of one of the lights 1410, may cause the lights 1410 to flash or pulsate, etc.

The controller 1440 may receive user inputs via a user interface 1460, and the light control module 1442 may control the lights 1410 based on the user inputs. For example, the user interface 1460 may include a turn signal switch, and light A 1411 may be a directional indicator. When a user engages the turn signal switch, the light control circuit 1442 may cause light A 1411 to flash to indicate the user's intention to turn or change lanes. As another example, the user interface 1460 may include a brake, and light B 1412 may be a brake light. When the user engages the brake, the light control circuit 1442 may cause light B 1412 to illuminate to indicate that the vehicle 1400 is slowing. Light C 1413 may be a headlight that illuminates in response to a user input or to detected low light conditions. Thus, during active operation of the vehicle 1400, the lights 1410 may function as is common in traditional vehicles, such as cars or trucks. When the vehicle 1400 is a lift device, such as a boom lift or telehandler, other external or internal lights may be controlled by the light control circuit 1442.

In some embodiments, when the battery 1450 of the vehicle 1400 is being charged (e.g., when the vehicle 1400 is not in active operation), the controller 1420 can control one or more of the lights 1410 to indicate the charge status of the battery 1450. In one example embodiment, light B 1412 may function as a battery charge status indicator. Light B 1412 may remain off when the battery 1450 is not being charged. Light B 1412 may flash on and off when the battery 1450 is actively being charged, but is not fully charged. Light B 1412 may remain on when the battery 1450 is fully charged. This may allow a user to view the charge status of one or more vehicles 1400 from a distance on a worksite without needing to view a smaller display on each vehicle 1400. If a user expects one or more vehicles 1400 to be charging, but their respective lights are not on or flashing, the user may inspect those vehicles 1400 to determine why they are not charging. If there are more vehicles 1400 than available chargers, a solid light from a battery charge status indicator on a first vehicle 1400 may indicate to the user that the first vehicle 1400 is fully charged and can be unplugged from the charger and put into service, and another vehicle 1400 can be plugged in and charged. In other embodiments, a light 1410 may indicate the charge status of the battery 1450 in other ways. For example, the light may change color or flash in various patterns to indicate the charge level of the battery 1450 and/or whether the battery 1450 is charging. For example, the controller 1420 may control a light such that the light emits a red light when the battery 1450 is at a low charge, emits a yellow light when the battery 1450 is at a medium charge, and emits a green light when the battery 1450 is near or at a full charge. The controller 1440 may be communicatively coupled to a user device, such as a smartphone, computer, tablet computer, or remote control. In some embodiments, the lights 1410 may remain off until an instruction is received from the user device to display the charge status of the battery 1450. For example, a user may make a selection on a smartphone app and an instruction may be sent from the smartphone to the controller 1440. The controller 1420 may then cause the light or lights 1410 to illuminate to display the charge status for a predetermined amount of time or until another instruction is received from the user device. This may allow the lights 1410 to turn off at times when the battery 1450 is charging and a user is not present or not looking at the vehicle 1400. The instruction may be sent to multiple vehicles 1400 simultaneously so that the charge status of each vehicle is indicated.

Using lights 1410 that are already present on the vehicle 1400 for use when the vehicle is in active operation as charge status indicators eliminates the need to design vehicles with additional single-function lights. Further, for vehicles and machines that have already been manufactured without dedicated charge status indicators, the existing safety lights (e.g., headlights, taillights, brake lights, etc.) may be used as indicators by modifying the software on the electronic control unit (e.g. controller 1440). Thus, in some embodiments, a vehicle 1400 may be retrofitted with a battery charge status indicator without physical modifications to the vehicle. It is contemplated, however, that a light may be a dedicated battery charge status indicator that does not have another function during operation of the vehicle 10. For example, light D 1414 may indicate the battery charge status during charging but may remain off during operation of the vehicle. If a vehicle is operational while charging, light D 1414 may indicate the battery charge status while the vehicle 1400 is in active operation.

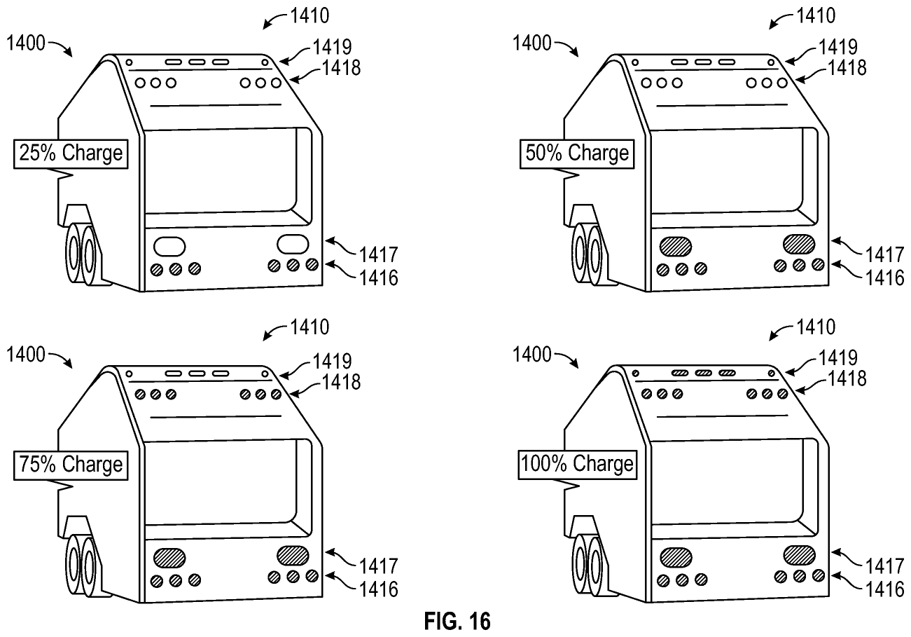

Referring now to FIG. 16, a method of using multiple lights 1410 to indicate battery charge status is illustrated, according to some embodiments. FIG. 16 shows a portion of a vehicle 1400 in four states. In the top left, the vehicle 1400 is shown when the battery 1450 is charged to 25 percent capacity. Of all of the lights 1410, only a first set of lights 1416 is illuminated, while the other lights 1410 remain off. In the top right, the vehicle 1400 is shown when the battery 1450 is charged to 50 percent capacity. Of all of the lights 1410, the first set of lights 1416 and a second set of lights 1417 are illuminated, while the other lights 1410 remain off. In the bottom left, the vehicle 1400 is shown when the battery 1450 is charged to 75 percent capacity. Of all of the lights 1410, the first set of lights 1416, the second set of lights 1417, and a third set of lights 1418 are illuminated, while the other lights 1410 remain off. In the bottom right, the vehicle 1400 is shown when the battery 1450 is charged to 100 percent capacity. All of the lights 1410, including the first set of lights 1416, the second set of lights 1417, the third set of lights 1418, and a fourth set of lights 1419 are illuminated, indicating that the battery 1450 is fully charged. It should be understood that the method shown in FIG. 16 is illustrative, and other embodiments are contemplated. For example, one light 1410 at a time may be illuminated as the battery charge level increases, or the lights may be illuminated from top to bottom, left to right, or right to left, rather than from bottom to top. One or more of the lights may flash to indicate that the battery 1450 is actively charging. When the battery 1450 is below a threshold charge (e.g., below 1%, below 10%, below 25%, etc.), the controller may control the lights 1410 such that none of the lights are illuminated, or such that one or more lights 1410 flash to indicate that the battery 1450 is actively charging, with none of the lights 1410 being steadily illuminated. In some embodiments, the lights 1410 may be configured to emit different colored light depending on the charge status of the battery 1450. For example, all of the lights 1410 may emit red light when the battery 1450 is at a low charge, emit yellow light when the battery 1450 is at a medium charge, and emit green light when the battery 1450 is near or at a full charge. In some embodiments, the various lights 1410 may emit different colors to indicate the charge status. For example, a first percentage of the lights 1410 may emit green light indicating a percentage of full battery charge, while the remaining lights 1410 emit red light indicating the amount of charge remaining to achieve full charge. In each of the preceding embodiments, the lights 1410 may provide a safety function and/or may provide visibility to a user of the vehicle 1400 when the vehicle 1400 is in active operation (e.g., headlights, tail lights, brake lights, cabin dome lights, etc.).

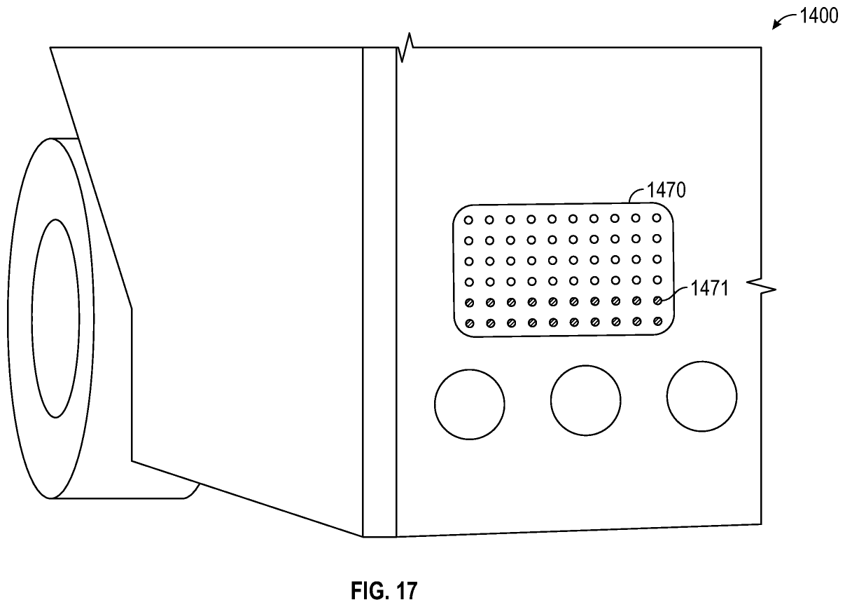

Referring now to FIG. 17, a method of using one light 1470 including multiple bulbs 1471 to indicate battery charge status is illustrated, according to some embodiments. Vehicle lights 1410 may be manufactured with multiple individual bulbs. For example, a tail light may be manufactured with an array (e.g., row, rows, a grid, etc.) of light-emitting diodes (LEDs). Each LED may be separately controllable by the electronic control unit (e.g., controller 1440). The light 1470 is shown with six rows and ten columns of bulbs 1471. The light 1470 may indicate the charge status of the battery 1450 based on the number of bulbs 1471 that are illuminated. For example, as shown in FIG. 17, two of the six rows of bulbs 1471 are illuminated, which may indicate that the battery 1450 is 33 percent charged. In some embodiments, rows or columns may illuminate as the charge level of the battery 1450 increases. In other embodiments, individual bulbs 1471 may illuminate as the charge level of the battery 1450 increases. In some embodiments, the one light 1470 may be configured to emit different colored light depending on the charge status of the battery 1450. For example, all of the LEDs in the light 1470 may emit red light when the battery 1450 is at a low charge, emit yellow light when the battery 1450 is at a medium charge, and emit green light when the battery 1450 is near or at a full charge. In some embodiments, the various LEDs of the light 1470 may emit different colors to indicate the charge status. For example, a first percentage of the LEDs may emit green light indicating a percentage of full battery charge, while the remaining LEDs emit red light indicating the amount of charge remaining to achieve full charge. In some embodiments, a single light 1470 with a single bulb configured to emit various colors may be configured to indicate the charge status of the battery (e.g., red for low charge, yellow for partial charge, green for full charge, etc.). In each of the preceding embodiments, the light 1470 may provide a safety function and/or may provide visibility to a user of the vehicle 1400 when the vehicle 1400 is in active operation (e.g., a headlight, a tail light, a brake light, a cabin dome light, etc.).

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

The hardware and data processing components used to implement the various processes, operations, illustrative logics, logical blocks, modules and circuits described in connection with the embodiments disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the vehicle 10 and the systems and components thereof as shown in the various exemplary embodiments is illustrative only. Additionally, any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

1. A refuse vehicle comprising:
a battery configured to power the refuse vehicle;
a light; and
a controller electrically coupled to the battery and the light, the controller comprising one or more processors and a memory storing instructions that, when executed by the one or more processors, cause the controller to:
control the light to provide a safety function and/or provide visibility to a user of the refuse vehicle when the refuse vehicle is in active operation; and
control the light to indicate a charge status of the battery when the refuse vehicle is not in active operation.

2. The refuse vehicle of claim 1, wherein the light is one of a tail light, a directional indicator, a brake light, a headlight, an in-cabin light, a backup light, a daytime running light, or a hazard light.

3. The refuse vehicle of claim 1, wherein controlling the light to indicate a charge status of the battery comprises causing the light to remain on when the battery is fully charged, to remain off when the battery is not being charged, and flash on and off when the battery is being charged but is not fully charged.

4. The refuse vehicle of claim 1, wherein controlling the light to indicate a charge status of the battery comprises adjusting the color of the light based on the charge status.

5. The refuse vehicle of claim 1, wherein the instructions further cause the controller to receive a command from a user device and wherein the instructions cause the controller to control the light to indicate the charge status of the battery in response to receiving the command from the user device.

6. The refuse vehicle of claim 1, wherein the light comprises a plurality of bulbs and wherein controlling the light to indicate a charge status of the battery comprises illuminating a number of bulbs corresponding to a charge level of the battery.

7. The refuse vehicle of claim 1, wherein controlling the light to indicate a charge status of the battery comprises adjusting the brightness of the light based on the charge level of the battery.

8. A vehicle comprising:
a battery configured to power the vehicle;
one or more lights; and
a controller electrically coupled to the battery and the lights, the controller comprising one or more processors and a memory storing instructions that, when executed by the one or more processors, cause the controller to:
control the lights to indicate a charge status of the vehicle.

9. The vehicle of claim 8, wherein controlling the lights to indicate a charge status of the battery comprises illuminating a number of lights based on a charge level of the battery.

10. The vehicle of claim 8, wherein the controller is configured to be connected to an external power supply, wherein controlling the lights to indicate a charge status of the battery comprises directing power from the power supply to the lights.

11. The vehicle of claim 8, wherein the instructions further cause the controller to control the lights to provide safety functions and/or provide visibility to a user of the vehicle when the vehicle is in active operation, wherein each light is one of a tail light, a directional indicator, a brake light, a headlight, an in-cabin light, a backup light, a daytime running light, or a hazard light.

12. The vehicle of claim 8, wherein controlling the lights to indicate a charge status of the battery comprises causing one of the plurality of lights to flash on and off when the off when the battery is being charged but is not fully charged.

13. The vehicle of claim 8, wherein the instructions further cause the controller to receive a command from a user device and wherein the instructions cause the controller to control the lights to indicate the charge status of the battery in response to receiving the command from the user device.

14. The vehicle of claim 13, wherein the lights are controlled to indicate the charge status is displayed for a predetermined amount of time in response to receiving the command from the user device.

15. The vehicle of claim 8, wherein the plurality of lights form a plurality of rows of lights, wherein controlling the lights to indicate a charge status of the battery comprises illuminating a number of rows of lights based on a charge level of the battery.

16. The vehicle of claim 8, wherein controlling the lights to indicate a charge status of the battery comprises illuminating all of the lights when the battery is fully charged and illuminating none of the lights when the battery is below a threshold level of charge.

17. The vehicle of claim 8, wherein controlling the lights to indicate a charge status of the battery comprises illuminating all of the lights when the battery is fully charged and causing one or more lights to flash on and off when the battery is charging and is below a threshold level of charge.

18. A method of operating a battery-powered vehicle having a battery and a plurality of lights configured to provide safety functions and/or provide visibility to a user of the vehicle, the method comprising:
determining a charge status of the battery; and
controlling the lights to indicate the charge status of the battery.

19. The method of claim 18, wherein controlling the lights to indicate the charge status of the battery comprises illuminating a percentage of the lights corresponding to a percent of battery charge stored in the battery.

20. The method of claim 18, wherein controlling the lights to indicate the charge status of the battery comprises steadily or periodically illuminating one or more of the lights when the battery charge is increasing.
